(19) United States
(12) Patent Application Publication
(10) Pub. No.: US 2015/0226807 A1
(43) Pub. Date: Aug. 13, 2015

(54) DETERMINATION OF NOMINAL CELL RESISTANCE FOR REAL-TIME ESTIMATION OF STATE-OF-CHARGE IN LITHIUM BATTERIES

(71) Applicant: Seeo, Inc, Hayward, CA (US)

(72) Inventors: Albert Aumentado, El Cerrito, CA (US); Scott Allen Mullin, San Leandro, CA (US); Mohit Singh, Santa Clara, CA (US)

(21) Appl. No.: 14/618,902

(22) Filed: Feb. 10, 2015

Related U.S. Application Data
(60) Provisional application No. 61/939,072, filed on Feb. 12, 2014.

(30) Foreign Application Priority Data
May 13, 2014 (CN) 2014-10200256.7

(51) Int. Cl. G01R 31/36; H01M 10/42

(52) U.S. Cl. CPC G01R 31/3624; H01M 10/4257; H01M 2010/4271; H01M 2220/20

(57) ABSTRACT

A functional relation relationship has been established between SOC, nominal resistance (Rₙₒₘ) and average applied load (P_{avg}), such that a function f(Rₙₒₘ, P_{avg})=SOC can be determined empirically. Load can be described using either average power or average current. The cell is tested initially to determine the relationships among these values prior to operation to create a look-up table. During operation, Rₙₒₘ and P_{avg} can be sampled with no cell down time and can be used as input parameters with the look-up table to determine SOC accurately.

### CROSS-REFERENCE TO RELATED APPLICATIONS

This application claims priority to U.S. Provisional Patent Application 61/939,072, filed Feb. 12, 2014 and to Chinese Patent Application 2014-10200256.7, filed May 13, 2014, both of which are incorporated by reference herein.

### BACKGROUND OF THE INVENTION

### Field of the Invention

This invention relates generally to methods for determining state of charge for secondary batteries, and, more specifically, to using battery current and voltage parameters in real time to determine same.

Real-time estimation of battery current and voltage parameters can be used to provide additional information about a cell's state-of-charge and state-of-health.

State of charge (SOC) is the equivalent of a fuel gauge for the battery pack in a battery electric vehicle (BEV), hybrid vehicle (HEV), or plug-in hybrid electric vehicle (PHEV). SOC is usually expressed as a percentage of full charge (e.g., 0%=empty; 100%=full). An alternate form of the same measure is the depth of discharge (DoD), the inverse of SOC (e.g., 100%=empty; 0%=full). SOC is normally used when discussing the current state of a battery in use, while DoD is most often used when discussing the capacity utilization of a cell during performance rating or cycle life testing.

State-of-charge (SOC) and state-of-health (SOH) are important parameters for monitoring and controlling battery cells, but they can be difficult to determine in many cases. SOH is typically estimated by tracking a cell's accessible capacity.

For battery chemistries where the open-circuit voltage (OCV) decreases continuously during discharge, there is a reasonable correlation between the open-circuit voltage and the SOC. However, this method requires the system to be disconnected from load periodically and in real world applications where a battery system may be under operation for the majority of its life, this is impractical. In chemistries where the OCV changes significantly with SOC, and in which the deviations from OCV under load conditions are relatively small, voltages under load can be used as a close proxy for the OCV. Thus, the voltage along with the amount of current passed into and out of the cell can be used to make an estimate of the SOC. For such battery chemistries, these estimates are often good enough for most purposes.

But for some other battery chemistries, the open-circuit voltage does not decrease continuously during discharge. For example, in a cell with a lithium metal anode and a LiFePO₄ cathode, the open-circuit voltage decreases at the very beginning of discharge and then remains stable throughout most of the discharge until it finally drops at the end. As the cell continues to discharge, the SOC decreases whereas the open-circuit voltage remains nearly constant. This relatively flat open-circuit voltage curve is not useful in trying to determine the SOC of such a cell. Additional methods to mitigate these factors include application of Kalman Filter theory, accurate Coulomb counting (current integration), and/or a priori determined complex RC circuit model fitting. However, these additional methods have further limitations and can be impractical to implement depending on the battery chemistry, pack design, or available electronics.

Another method, known as current accounting or Coulomb counting, calculates the SOC by measuring the battery current and integrating it over time. Problems with this method include long-term drift, lack of a reference point, and, uncertainties about a cell's total accessible capacity (which changes as the cell ages) and operation history. Only fully-charged or fully-discharged cells have well-defined SOCs (100% and 0%, respectively).

SOH determination is similarly convoluted—accurate capacity determination is difficult in dynamic usage scenarios due to errors in Coulomb counting. These problems are particularly compounded in lithium-polymer cells in which transport limitations give rise to significant cell polarization, which obscures voltage end-point determination under load.

Some methods of SOC determination involve fitting complicated resistor-capacitor (RC) circuit models to a priori tests in order to model dynamic cell behavior. However, those methods are very complicated, computationally intensive, and are indirect, all of which can contribute to errors and cost. Moreover, such methods are set up in advance, and are not used to predict real-time status indicators.

What is needed is a simple, direct, accurate method to determine the SOC for rechargeable batteries.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a plot that shows Rₙₒₘ (nominal resistance) as a function of SOC (State-of-Charge) for two different simple load and pulse durations.

FIG. 2 is an exemplary voltage profile that can be used by a battery tester for imposing a complex dynamic stress load on a cell.

FIG. 3 is an example of data parsing based on small regions of charge and discharge.

FIG. 4 is a plot that shows Rₙₒₘ as a function of SOC under three different complex dynamic stress load conditions such as those shown in FIG. 2.

### SUMMARY

A method of determining the state of charge for a battery cell in real time is disclosed. The method involves:
a) measuring voltage and current values as a function of time while the battery cell is operating;
b) recording in a memory location the voltage and the current values over various time periods
c) determining a nominal resistance associated with each time period from recorded the voltage and current values in the memory location using a computer processor;
d) recording in a memory location data pairs of the nominal resistance with the associated time period;
e) determining the state of charge of the battery cell by comparing, using a computer processor, the data pairs to a previously-populated look-up table in a memory location, wherein the look-up table correlates the data pairs to state-of-charge values.

The battery cell may have lithium metal as an anode, lithium iron phosphate as a cathode, and a polymer electrolyte as a separator.

In step (b), the time periods may range from about 0.5 to 60 seconds. In step (c), determining a nominal resistance involves using the following expression to calculate the nominal resistance (Rₙₒₘ):

$${R}_{nom} = \frac{{OCV}_{nom} - {V}_{avg}}{{I}_{avg}}$$

wherein OCVₙₒₘ is a nominal open circuit voltage, V_{avg} is a time-averaged voltage value, and I_{avg} is a time-averaged current value. V_{avg} may be given by:

$${V}_{avg} = \frac{1}{Δ T} \int V d t$$

where ΔT is the time period (in step (c)) and integration is performed over a time bounded discharge region.

In step (e), the previously-populated look-up table may be created by:
i. determining a total capacity of the cell in total Coulombs;
ii. using a battery tester to count Coulombs moving into and out of a representative cell as the tester pulls and pushes current according to a predetermined program over an entire capacity range of the cell to generate a look-up table that comprises associated values of voltage as a function of time and of Coulombs as a percentage of total Coulombs in the cell (SOC);
iii. storing the look-up table in a memory location; and
iv. using a microprocessor to calculate nominal cell resistances for various time periods in the curve and storing the nominal cell resistances in the look-up table.
   and the microprocessor is programmed to perform a linear interpolation between values in the look up table as needed.

In another aspect of the invention, a computer-readable medium is disclosed. The medium has code which, upon execution by a computer processor, implements a method, the method comprising:
1. measuring voltage and current values as a function of time while the battery cell is operating;
2. recording in a memory location the voltage and the current values over various time periods
3. determining a nominal resistance associated with each time period from the voltage and current values recorded in the memory location using a computer processor;
4. recording in a memory location data pairs of the nominal resistance with the associated time period;
5. determining the state of charge of the battery cell by comparing, using a computer processor, the data pairs to a previously-populated look-up table in a memory location, wherein the look-up table correlates the data pairs to state-of-charge values.

### DETAILED DESCRIPTION

The embodiments are illustrated in the context of State-of-Charge (SOC) measurements in a battery with a lithium metal anode and a LiFePO₄ cathode. The skilled artisan will readily appreciate, however, that the materials and methods disclosed herein will have application in a number of other contexts where accurate SOC determination is desirable, particularly where there is not an obvious functional relationship between open circuit voltage and SOC.

These and other objects and advantages of the present invention will become more fully apparent from the following description taken in conjunction with the accompanying drawings.

For the purposes of this disclosure, a “Nominal Resistance” is defined as.

$${R}_{nom} = \frac{{OCV}_{nom} - {V}_{avg}}{{I}_{avg}} [ Ohms ] \qquad ( 1 )$$

wherein OCVₙₒₘ is a nominal open circuit voltage that can be defined for the specific cell chemistry. In one example, the OCVₙₒₘ is the average equilibrium voltage over the full SOC range. In another example, the OCVₙₒₘ is the equilibrium OCV at a single SOC value. V_{avg} and I_{avg} are time-averaged values of voltage and current, respectively, and can be determined for a specific load application (e.g., 15 amp pulse for 30 seconds). Equations for determining these values are shown later in this disclosure.

In cell systems at high enough loads, the cell can become transport-limited due to the finite mobility of the charged species of interest intrinsic to the cell electrochemistry. For example, such a transport limitation can result in a concentration gradient that creates an additional voltage in the cell due to the biased polarization of charged species. The concept of nominal resistance has been introduced so that such deviations from nominal open circuit voltage can be taken into account.

### Initial Cell Characterization

Initially, when cells are manufactured, they undergo extensive quality testing. It can be assumed that cells that pass the tests are all starting out about the same. In one embodiment of the invention, one or more cells are subject to additional testing. In one arrangement, a fully-charged cell is connected to a precision battery testing device that is programmed to push current into and pull current out of the cell under various load conditions. Voltage is monitored and Coulombs are counted throughout the process so that SOC can be determined at any time. Nominal resistances are determined for various load durations using equation (1).

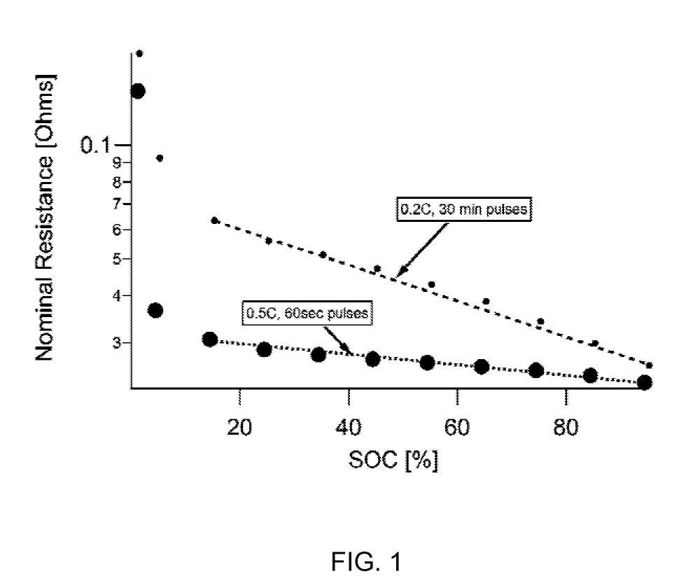

FIG. 1 is a plot that shows Rₙₒₘ (nominal resistance) as a function of SOC at two different simple applied loads and load durations: 30 minute pulses at 0.2C (the rate at which the battery would discharge fully over 5 hours), and 60 second pulses at 0.5C (the rate at which the battery would discharge fully over 2 hours). SOC was calculated based on the known rated capacity of the cell and accurate Coulomb counting (or alternatively current integration) from the precision battery testing device. It can be seen that nominal resistance is strongly dependent on SOC. Furthermore, the two curves can be distinguished by the load conditions.

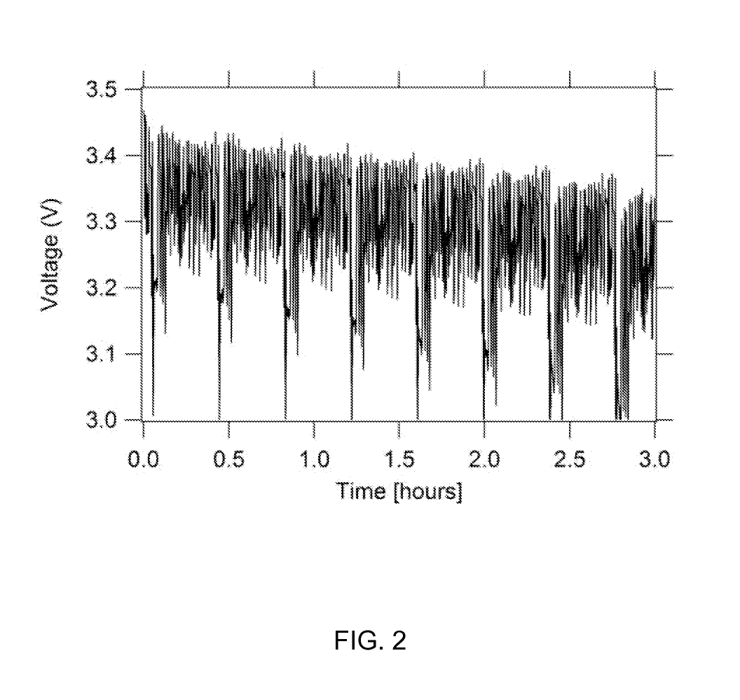

In another arrangement, a fully-charged cell is connected to a precision battery testing device that is programmed to push current into and pull current out of the cell as if the cell were experiencing complex dynamic stress loading. An example of a voltage profile (voltage vs time) for such a test is shown in FIG. 2. The voltage profile is a realistic and complex load profile that a cell may experience in actual operation, such as in an electric vehicle. The ability to measure SOC accurately as the battery is operating becomes critical when under highly dynamic stresses as there is no practical way to stop cell operation in order to measure SOC as many other methods require. The complex and dynamic load profile shown in FIG. 2 was repeated cyclically with a period of about 23 minutes until the cell reached 0% SOC.

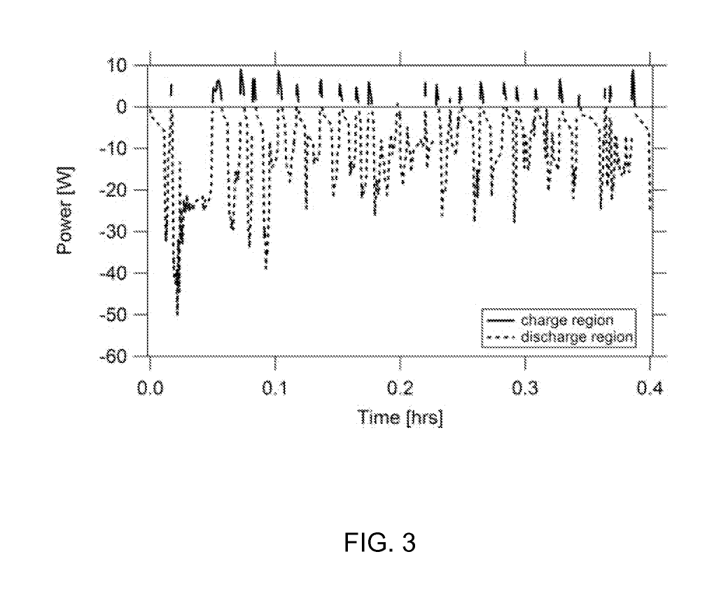

FIG. 3 is a different view of the data in FIG. 2, in which the x-axis is zoomed-in to highlight the complexity and dynamic nature of the load profile, and in which the y-axis is plotted as power. Power, the product of the instantaneous cell voltage and current across the terminals, clearly distinguishes regions of the profile in which the cell is discharging (shown here with the convention of negative power, corresponding to negative current) from regions in which the cell is charging (shown here with the convention of positive power, corresponding to positive current).

The data in FIG. 3 is parsed and binned by load condition. The load conditions are specified by a power (in units of W) and duration (in units of seconds), and are sorted into bins with relative widths of 1%. For example, a bin with power of 4.6 W and duration of 24.4 seconds captures all regions with power between 4.554 and 4.646 W and durations between 24.156 and 24.644 seconds. All of the data was binned into less than 20 load conditions.

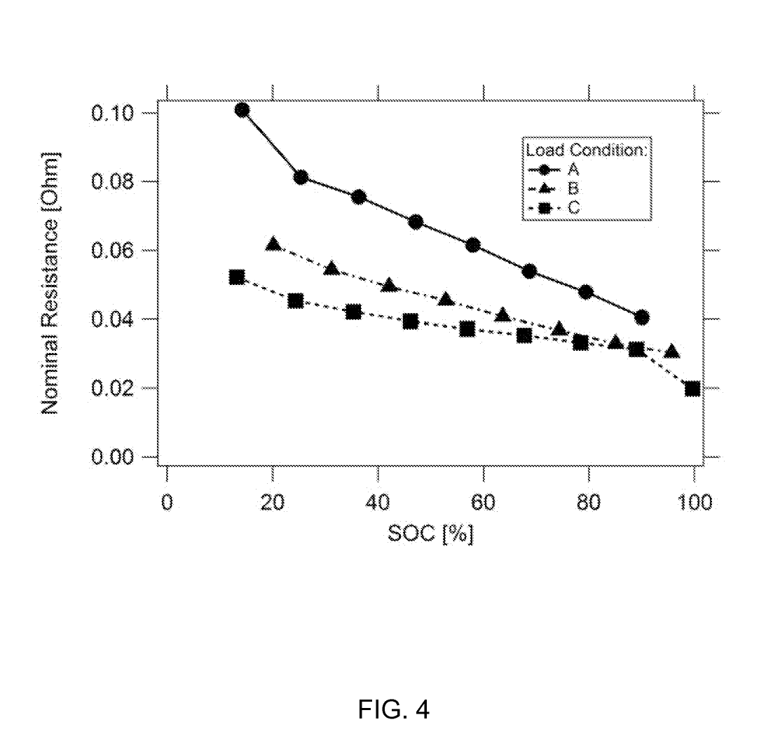

FIG. 4 is a plot that shows Rₙₒₘ (nominal resistance), as a function of SOC for the complex and dynamic load profile shown in FIG. 2. The Rₙₒₘ values in FIG. 4 were calculated for discharge regions, which were parsed as described above. For clarity, three load conditions are shown: Load Condition A is the highest load [14.9 W, 52.6 s], Load Condition B is an intermediate load [13.7 W, 10.4 s], and Load Condition C is the lowest load [4.6 W, 24.4 s].

Cell polarization is a dynamic and complicated phenomenon that depends strongly on duration, magnitude and direction of the applied power. Rₙₒₘ is strongly affected by the cell polarization. The skilled artisan will appreciate the foregoing information and understand that dynamic load conditions could be parsed and calculated in different ways—including combining charge and discharge regions and/or binning by net charge or energy passed—to obtain additional information than that presented herein. FIGS. 3 and 4 should be considered examples for illustrative purposes only.

Despite the dynamic and complex nature of the load profile in FIG. 2, the Rₙₒₘ values in FIG. 4 show a strong, clear dependence on SOC.

Results from either simple or complex cell testing conditions can be presented graphically as shown in FIGS. 1 and 4, or in a look-up table as shown below. For illustrative purposes only, a look-up table that might be created from some data is shown below.

| Nominal Resistance | SOC | Load Duration |
|---|---|---|
| 50 mΩ | 10% | 10 sec |
| 60 mΩ | 20% | 10 sec |
| 50 mΩ | 30% | 5 sec |

A lookup table is an array that replaces runtime computation with a simpler array indexing operation. The savings in terms of processing time can be significant, since retrieving a value from memory is often faster than undergoing an ‘expensive’ computation or input/output operation. The tables may be pre-calculated and stored in static program storage, calculated (or “pre-fetched”) as part of a program's initialization phase (memorization), or even stored in hardware in application-specific platforms.

In other implementations, the look-up table may contain additional or different information, including, but not limited to, average power, net charged passed (determined via Coulomb counting).

The time-averaged voltage V_{avg} and the time-averaged current I_{avg} for each region are given by:

$$\begin{matrix}{V}_{avg} = \frac{1}{Δ T} \int V d t & ( 2 ) \\ {I}_{avg} = \frac{1}{Δ T} \int I d t & ( 3 )\end{matrix}$$

where ΔT is the time duration of the load and integration is performed over the time bounded discharge region. In some arrangements, these average values can be calculated over the total duration of the load using common numerical integration methods, such as trapezoidal integration.

Once these values are determined, values for nominal resistance Rₙₒₘ under various load conditions can be calculated. The Rₙₒₘ and load duration can be associated with SOC through accurate Coulomb counting. These values can be used to populate a look-up table or create a graph that can be used as a reference during actual cell operation.

Some of the key advantages of the method as described herein include:
1. it is designed to be used as a battery pack is operating;
2. it is low-cost—only additional pack hardware is microprocessor and memory; and
3. it measures the SOC of each individual cell in the battery pack;
4. it can be used with dynamic battery loads.

The method can be used on the fly, while the battery pack is operating. No down time is required. This is a tremendous advantage. Packs are already designed to monitor voltage for each cell and current and time for the overall pack (which also applies to each cell). All data needed for this method is already collected in a normal battery management system (BMS). The only additional hardware that may be useful are a microprocessor and memory storage. In some embodiments of the invention, the microprocessor and memory storage of the BMS has enough capacity to carry out the SOC determination method without any additional hardware.

It is important to note that the method measures the SOC of each individual cell. In SOC determination methods that employ Coulomb counting for cells in series, errors can and do occur. Such methods cannot measure SOC for each cell, but rather get some kind of composite value. It is difficult to understand what such a composite value really means. For example, in some pack designs a 50% SOC composite value may mean that all cells are at 50% SOC. Or it may mean that half the cells are completely dead and half are at 100% SOC.

In various embodiment of the invention, the SOC dependent deviations using the nominal resistance Rₙₒₘ and known load conditions are captured as a means of parsing complex and dynamic data to provide a real-world practical method for estimating SOC during operation. This information can be used as a direct measure or to complement existing SOC estimation algorithms. Because this information is readily available throughout the lifetime of operation, there may also be an application in SOH estimation given the initial state of the system and how the deviations look over time.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. A method of determining the state of charge for a battery cell in real time comprising the steps of:
a) measuring voltage and current values as a function of time while the battery cell is operating;
b) recording in a memory location the voltage and the current values over various time periods
c) determining a nominal resistance associated with each time period from recorded the voltage and current values in the memory location using a computer processor;
d) recording in a memory location data pairs of the nominal resistance with the associated time period;
e) determining the state of charge of the battery cell by comparing, using a computer processor, the data pairs to a previously-populated look-up table in a memory location, wherein the look-up table correlates the data pairs to state-of-charge values.

2. The method of claim 1 wherein the battery cell comprises lithium metal as an anode, lithium iron phosphate as a cathode, and a polymer electrolyte as a separator.

3. The method of claim 1 wherein, in step (b), the time periods are from about 0.5 to 60 seconds long.

4. The method of claim 1 wherein, in step (c), determining a nominal resistance comprises using the following expression to calculate the nominal resistance (Rₙₒₘ):
$${R}_{nom} = \frac{{OCV}_{nom} - {V}_{avg}}{{I}_{avg}}$$
wherein OCVₙₒₘ is a nominal open circuit voltage, V_{avg} is a time-averaged voltage value, and I_{avg} is a time-averaged current value.

5. The method of claim 4 wherein V_{avg} is given by:
$${V}_{avg} = \frac{1}{Δ T} \int V d t$$
and I_{avg} is given by:
$${I}_{avg} = \frac{1}{Δ T} \int I d t$$
where ΔT is the time period (in step (c)) and integration is performed over a time bounded discharge region.

6. The method of claim 1 wherein, in step (e), the previously-populated look-up table is created by:
determining a total capacity of the cell in total Coulombs;
using a battery tester to count Coulombs moving into and out of a representative cell as the tester pulls and pushes current according to a predetermined program over an entire capacity range of the cell to generate a look-up table that comprises associated values of voltage as a function of time and of Coulombs as a percentage of total Coulombs in the cell (SOC);
storing the look-up table in a memory location; and
using a microprocessor to calculate nominal cell resistances for various time periods in the curve and storing the nominal cell resistances in the look-up table.

7. The method of claim 1 wherein, in step (e), the microprocessor is programmed to perform a linear interpolation between values in the look up table as needed.

8. A computer-readable medium comprising code which, upon execution by a computer processor implements a method, the method comprising:
a) measuring voltage and current values as a function of time while the battery cell is operating;
b) recording in a memory location the voltage and the current values over various time periods
c) determining a nominal resistance associated with each time period from the voltage and current values recorded in the memory location using a computer processor;
d) recording in a memory location data pairs of the nominal resistance with the associated time period;
e) determining the state of charge of the battery cell by comparing, using a computer processor, the data pairs to a previously-populated look-up table in a memory location, wherein the look-up table correlates the data pairs to state-of-charge values.

9. The computer-readable medium of claim 8 wherein the battery cell comprises lithium metal as an anode, lithium iron phosphate as a cathode, and a polymer electrolyte as a separator.
